(19) United States
(12) Patent Application Publication
(10) Pub. No.: US 2014/0238639 A1
(43) Pub. Date: Aug. 28, 2014

(54) MODULAR ENCLOSURE SYSTEM AND KIT FOR CONTAINING AND REGULATING AIRFLOW

(71) Applicant: Level 3 Communications, LLC, Broomfield, CO (US)

(72) Inventors: Robert Ambriz, Firestone, CO (US); Nasser Nabih El-Aawar, Denver, CO (US)

(73) Assignee: Level 3 Communications, LLC, Broomfield, CO (US)

(21) Appl. No.: 14/192,506

(22) Filed: Feb. 27, 2014

Related U.S. Application Data
(60) Provisional application No. 61/770,218, filed on Feb. 27, 2013.

(51) Int. Cl. H05K 7/20

(52) U.S. Cl. CPC H05K 7/20745
USPC 165/57

(57) ABSTRACT

A modular enclosure system and kit for containing and regulating the flow of air in and around data center and gateway facility equipment (e.g., server racks, equipment racks, cabinets, data storage libraries). The modular enclosure system can readily be adapted to differing types of equipment and to the differing cooling needs of different equipment. The system includes lightweight, thermally insulated, modular, interconnectable wall and ceiling panels adapted to enclose the equipment and an inflow of cool air, vent panels adapted to regulate the flow of air into and out of the enclosure, and cable ports that allow cables to pass into and out of the enclosure while minimizing bypass airflow.

### CROSS REFERENCE TO RELATED APPLICATIONS

This application claims priority under 35 U.S.C. §119 to U.S. provisional patent application No. 61/770,218, which was filed on Feb. 27, 2013, entitled “MODULAR ENCLOSURE SYSTEM FOR CONTAINING AND REGULATING AIRFLOW” and is hereby incorporated by reference in its entirety into the present application.

### TECHNICAL FIELD

Aspects of the present disclosure involve a modular enclosure system and kit for enclosing various types of equipment in data centers and gateway facilities (e.g., server racks, equipment racks, cabinets, storage libraries) in order to thermally manage the equipment.

### BACKGROUND

Data centers and gateway facilities consume massive amounts of energy, not only from the various computer, telecommunications, and storage systems in the facilities, but also from the respective cooling systems needed to manage the heat generated by the equipment. With continuing expansion of computing networks, rising energy costs, and a desire to operate sustainable facilities, the need to efficiently manage energy consumption in data centers and gateway facilities becomes increasingly important. While facility operators may have somewhat limited control over the energy consumed by each piece of equipment in the data center or gateway facility, operators can control the manner in which the equipment is thermally managed.

A data center is a computing hub that contains servers and storage equipment that run application software that processes and stores content and data. A gateway facility, on the other hand, is a telecommunications hub, or node, that processes and routes various forms of communication (e.g., phone calls, web browsing, streaming video) through a vast network of interconnected nodes, networks, and users. While data centers and gateway facilities may perform different functions, both facilities use similar, and often the same, equipment (e.g., servers, routers, switches, server appliances, storage libraries) and face the same thermal management challenges.

In order to keep the equipment running optimally, the layout of data centers and gateway facilities are designed in conjunction with the heating, ventilation, and air-conditioning (HVAC) systems or, more particular to this type of environment, the computer room air-conditioning (CRAC) system. Because most server and gateway type equipment are mounted on standardized racks, and the equipment is designed to intake cool air in the front of the unit and exhaust hot air in the back of the unit, the CRAC system is designed to flow cool air to the front of the equipment racks and to pull hot air from back of the racks for recirculation into the CRAC system.

Often, equipment racks in a data center or gateway facility are arranged in a “hot and cold” aisle arrangement. Referring to FIG. 1, equipment racks are aligned in sets of two rows such that the back of the equipment racks face each other and the front of the racks face outward. In this arrangement, the “hot” aisle is the space formed in between the backs of the racks of equipment and the cold aisles are located at the fronts of the racks. Alternatively and referring to FIG. 2, the equipment racks can be aligned in a single row, with the front of the racks in close proximity to the flow of cool air. While not containing the hot and cold air spaces, the previously described arrangements generally localize the hot and cold air by creating a “cold” aisle in front of the server racks and a “hot” aisle in back of the server racks.

Many factors contribute to the challenges of thermal management in data centers and gateway facilities. With ever changing needs of customers and advances in technology, many data centers and gateway facilities contain a mixture of new and legacy equipment that vary in size, shape, cooling requirements, and estimated life.

Some equipment, including certain stand-alone units (e.g., data storage libraries), do not fit into standard 19 inch or 23 inch racks and/or does not lend itself well to a “hot and cold” aisle arrangement. While some large data centers may have multiple rows of racks that are substantially the same size and shape, not all data centers are so uniform. As far as cooling requirements, some equipment requires very little cooling (e.g., small tape library), whereas some equipment requires much more cooling (e.g., typical server). While it is convenient to align multiple pieces of equipment in a single row, it is an inefficient use of energy to place equipment with differing cooling requirements in a row, if all equipment is equally cooled.

With these thoughts in mind among others, aspects of the modular enclosure system disclosed herein were conceived.

### SUMMARY

Aspects of the present disclosure involve a modular enclosure system for containing and regulating airflow around data center or gateway facility equipment. The system may comprise a plurality of interconnectable panels adapted to form a first enclosure for containing a plurality of electronic equipment and at least a portion of an airflow from a cold air source. Each interconnectable panel may include an outer edge with at least a portion of the outer edge defining a first interconnection pattern, the first interconnection pattern connectable to a second interconnection pattern of an adjacent interconnectable panel to form at least one of a parallel or orthogonal interconnection between the adjacent interconnectable panels. The first enclosure may comprise a first opening for intaking the at least a portion of the airflow from a cool air source at a first inflow rate into the first enclosure, wherein the at least a portion of the airflow cools the equipment. The first enclosure may also comprise a second opening for exhausting the at least a portion of the airflow out of the first enclosure at a first outflow rate, the second opening comprising a flow-through area that regulates the first outflow rate of the at least a portion of the airflow out of the first enclosure thereby regulating the first inflow rate of the at least a portion of the airflow into the first opening.

Aspects of the present disclosure may also involve a modular enclosure kit for containing and regulating airflow around data center or gateway facility. The kit may comprise a plurality of interconnectable panels, each interconnectable panel defining an outer edge with at least a portion of the outer edge defining a first interconnection pattern, the first interconnection pattern connectable to a second interconnection pattern of an adjacent interconnectable panel to form at least one of a parallel or orthogonal interconnection between the adjacent interconnectable panels. The plurality of interconnectable panels are adapted to assemble a first enclosure by interconnecting the plurality of interconnectable panels to form an enclosure around electronic equipment to be cooled and at least a portion of an airflow from a cool air source. The enclosure may comprise a first opening for intaking a portion of a cool airflow to cool the electronic equipment. Additionally, the enclosure may comprise a second opening for exhausting the portion of the cool airflow out of the first enclosure, wherein a size of the second opening is adjustable such that regulating the portion of the cool airflow out of the first enclosure thereby regulates the portion of the cool airflow into the first opening of the enclosure.

Additionally, other embodiments are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modification in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

Example embodiments are illustrated in referenced figures of the drawings. It is intended that the embodiments and figures disclosed herein are to be considered illustrative rather than limiting.

FIG. 1 (prior art) is a side view of a conventional “hot and cold” aisle arrangement with two rows of equipment racks;

FIG. 2 (prior art) is a side view of a conventional “hot and cold” aisle arrangement with one row of equipment racks;

FIG. 3 is a side view of the modular enclosure system;

FIG. 4 is an isometric view of the modular enclosure system of FIG. 3;

FIGS. 5A-5D are front views of interconnectable wall and ceiling panels with interlocking teeth;

FIG. 6 is a front view of a first interconnectable panel with interlocking teeth and a side view of a second interconnectable panel with corresponding interlocking teeth at a right angle to the first panel;

FIG. 7 is an isometric view of an enclosure with a T-shaped member supporting and transmitting the force from the ceiling panels to the load-bearing wall panels;

FIG. 8 is a transparent side view of the modular enclosure system that depicts the airflow in and out of the equipment on the rack;

FIG. 9 is a transparent side view of the modular enclosure system with a slanted front panel assembly that directs the airflow toward the equipment on the rack;

FIG. 10 is an isometric view of a modified ceiling or wall panel and venting element with an adjustable flow-through area;

FIG. 11 is an isometric view of a modified ceiling or wall panel with cutout markers indicating differing flow-through areas;

FIG. 12A is an isometric view of a modified ceiling or wall panel and a grommet insert with brushes;

FIG. 12B is an isometric view of a modified ceiling or wall panel and a split grommet insert with brushes; and

FIG. 13 is an isometric view of a modified ceiling or wall panel with a grommet insert with brushes and with a venting element with an adjustable flow-through area.

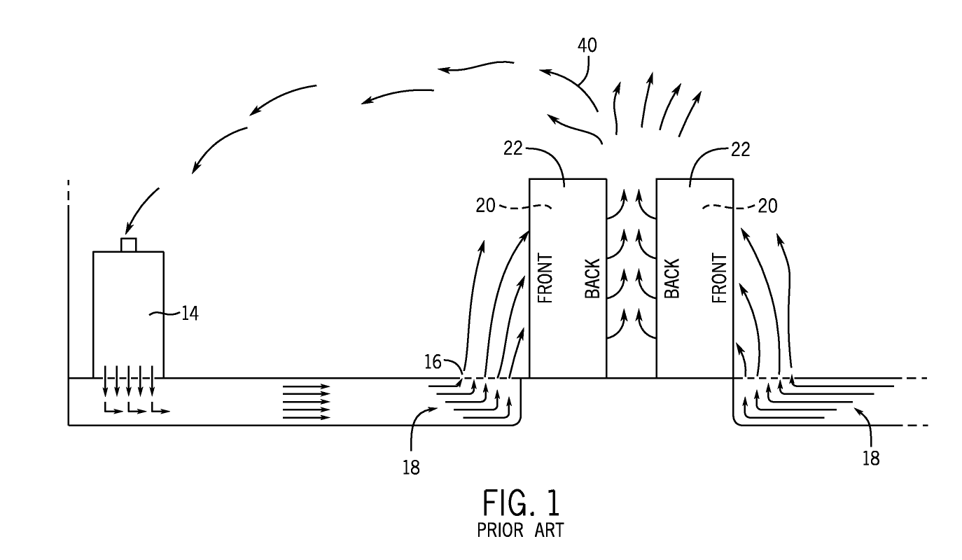

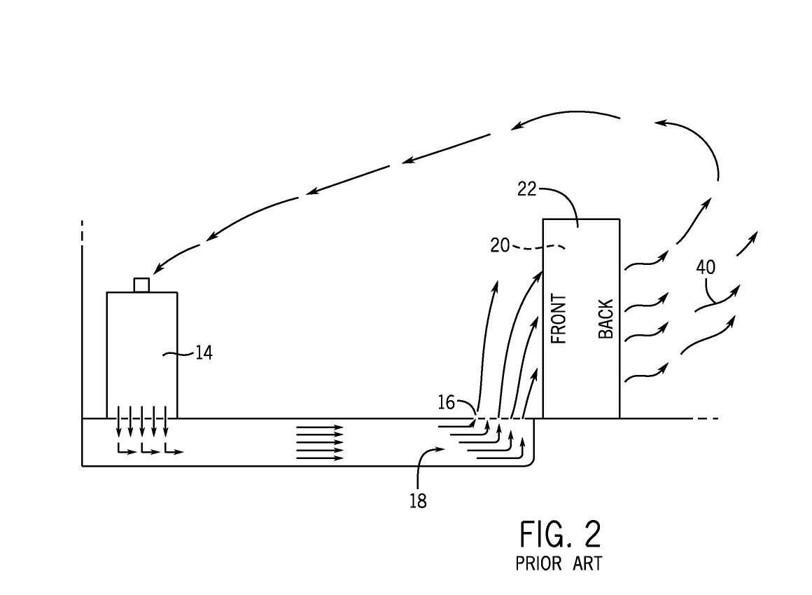

### DETAILED DESCRIPTION

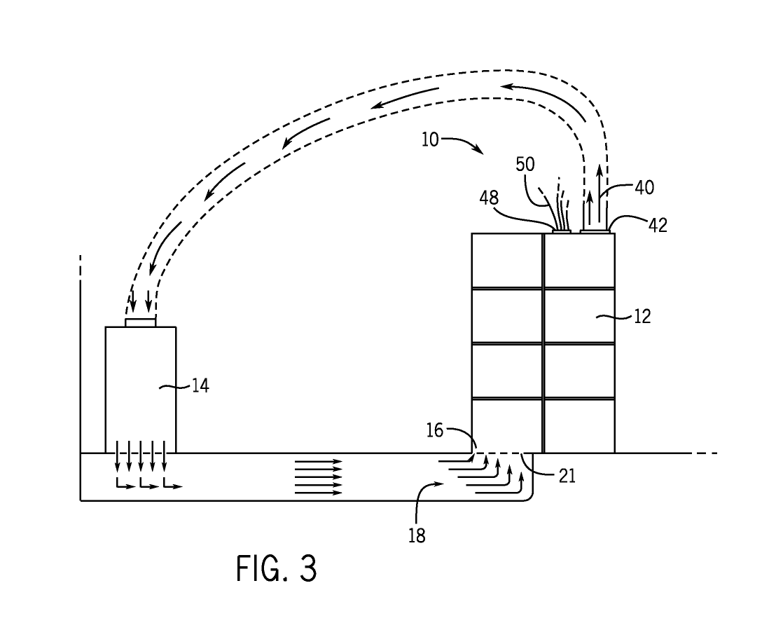

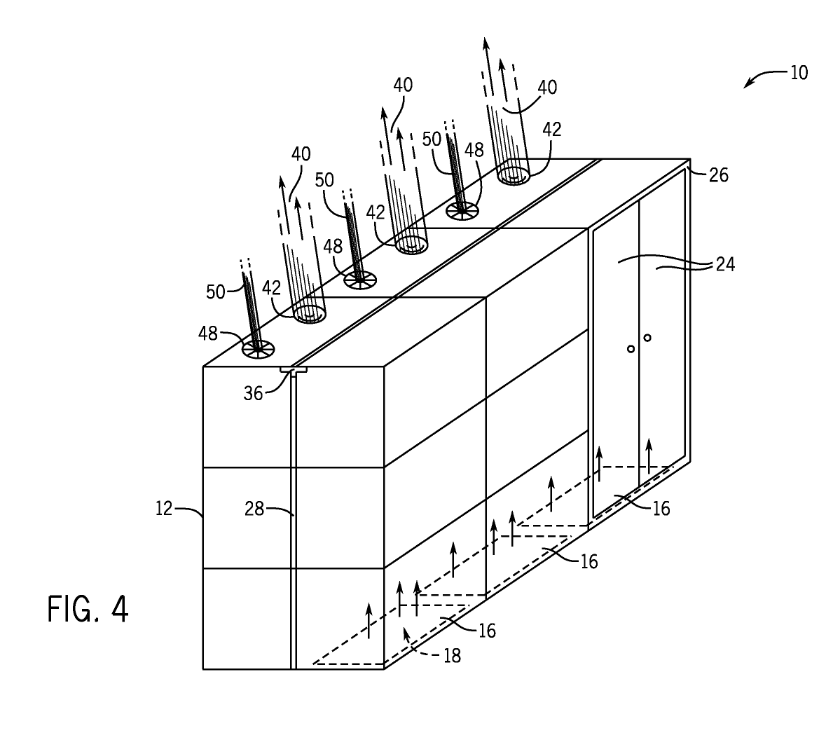

Aspects of the present disclosure involve a modular enclosure system and kit for containing and regulating the flow of air in and around data center and gateway facility equipment (e.g., server racks, equipment racks, cabinets, data storage libraries). The modular enclosure system can readily be adapted to differing types of equipment and to the differing cooling needs of different equipment. The enclosure system 10, as depicted in FIGS. 3-4, comprises lightweight, thermally insulated, modular, interconnectable wall and ceiling panels 12 that can be constructed to form an enclosure around equipment of varying size. The enclosure system 10 integrates with the HVAC or CRAC system 14 in the data center or gateway facility by enclosing the equipment 20 and the floor space, or a portion thereof, that supplies cool air 18 to the equipment 20. The system 10 encloses the floor space in an intake area 21 above the perforated floor tiles 16 that supplies cool air 18 to the equipment 20 in the racks 22. The cool air 18 from the intake area 21 cools the enclosed equipment 20, and the equipment 20 exhausts warm air 40 out the back of the equipment 20, often via a fan contained within the equipment 20. The enclosure system 10 provides an elegant means to regulate the amount of cooling within each enclosure. The system 10 also provides a means for cables 50 to pass into and out of the enclosure while minimizing bypass airflow.

A modular type of enclosure system 10 allows a data center or gateway facility worker to easily custom fit an enclosure around a single piece or multiple pieces of equipment 20. For example, a data storage library that is scheduled to perform backups on a daily basis, which may require a small amount of cooling, can be separately enclosed from a row of racks populated with high powered servers, which will likely require more cooling than the tape library. The modular wall and ceiling panels 12 are constructed of a lightweight material with thermal insulating properties such that there is minimal heat transfer from the warmer air outside the enclosure into the cooler air 16 inside the enclosure. The wall panels 12 are of a suitable dimension such that the entire enclosure system 10 can be scaled to fit any size of unit or row of units. Since most types of equipment in data centers and gateway facilities are housed on standard sized racks 22 that are 19 inches or 23 inches wide, the front and rear modular wall panels 12 can be dimensioned to fit these standard sizes. The height of the wall panels 12 can be somewhat standardized to enclose a standard rack size of 42U tall. The industry standard rack height of 42U consists of 42 single “rack units” (i.e. 1 U) that are each 1.75 inches high. Since the depth of racks 22 is not so standardized, the side wall panels 12 can be dimensioned to fit varying depths or there can be multiple sizes for the side wall panels 12. The exact dimensions of the panels can vary accordingly. For example, the panel 12 dimensions can be such that it provides clearance for racks 22 with cabinet-type enclosures as well as racks 22 without cabinet-type enclosures.

Since both the front and the rear of the equipment 20 on the rack 22 generally contain the instrument panel and most of the wiring, these areas are often accessed for maintenance, support, addition of equipment to the rack, etc. Referring to FIG. 4, the modular enclosure system 10 can include one or more doors 24 on the front and/or rear of the enclosure. A door 24 can be installed in place of a section of panels 12, wherein the framing 26 of the door 24 can connect with the surrounding panels 12. A door 24 on the front and/or rear of the enclosure system 10 provides easy and convenient access to the equipment 20 in the rack 22 or the rack itself 24. For larger enclosure systems 10, especially rows of racks 22 and racks 22 that require regular access, doors 24 may provide easy and convenient access to the equipment 20. For smaller enclosure systems 10, such as an enclosure of a single unit 20 or only a couple of racks 22 of equipment 20, the front and rear wall panels 12 can be accessed by disengaging and removing the interconnecting panels 12. Removal of panels 12 in order to access the front or rear of the rack 22 will not affect the structural integrity of the entire system 10 since the panels 12 interconnect and, thus, the load will be distributed to the surrounding panels 12. The decision of whether to install doors 24 or panels 12 on the front and/or rear of the enclosure system 10 will be dependent on the access needs of the equipment 20. An advantage of the modular enclosure system 10 is the ease of assembly and the customizable options. For example, if panels 12 were initially installed in the front and rear of the enclosure 10, the panels 12 can later be swapped out for a door 24 or an openable panel 12 and vice versa.

The wall and ceiling panels 12 can be structured panels, wherein the panels provide the load bearing support for the enclosure. In this orientation, the panels 12 connect to other panels 12 while maintaining the structural integrity of the entire enclosure 12. On the other hand, the wall and ceiling panels 12 can fit into a frame 28 that encloses the equipment 20 and supports the structural load of the frame 28 and panels 12. In this orientation, first, the frame 28 is custom fit and constructed around the enclosure 10, and second, the panels 12 are placed into the frame 28.

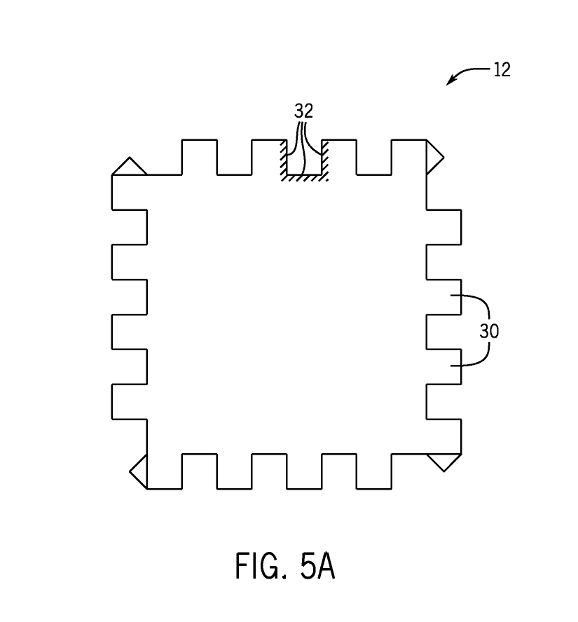

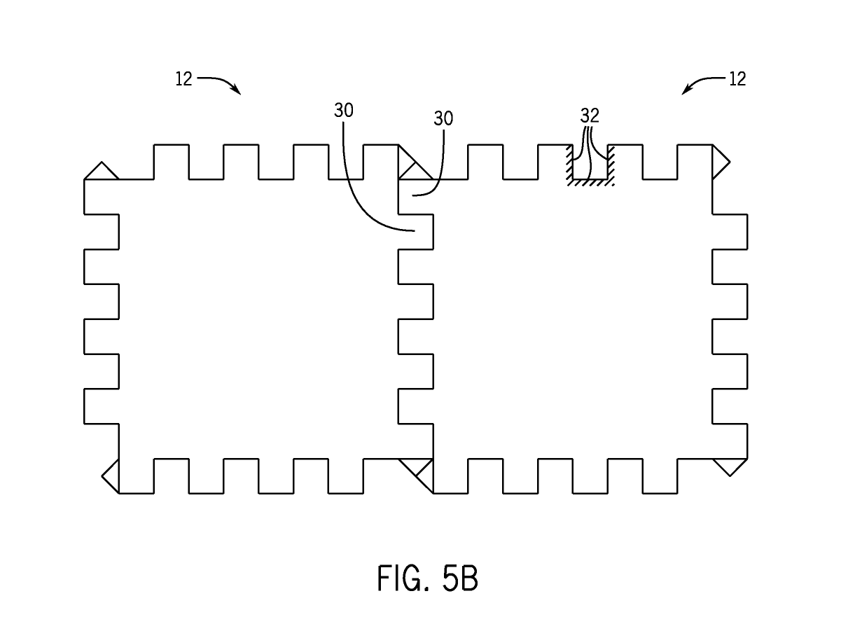

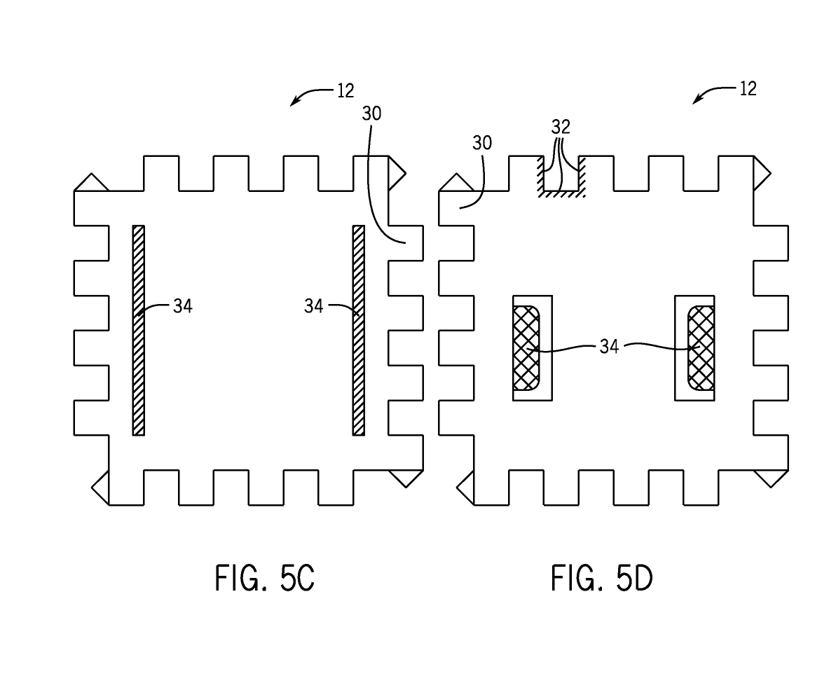

Referring to FIG. 5A, the wall and ceiling panels may comprise interlocking teeth 30. FIG. 5B depicts two interconnected panels 12. In these particular embodiments, the panels 12 are structured panels, wherein the panels support the weight of the enclosure system 10. Also, in these particular embodiments, the interlocking teeth may define a square-wave pattern. The interlocking teeth 30 connect the panels 12 together and the friction between the teeth 30 holds the panels 12 in place. In order to ease assembly and disassembly of the enclosure 10, the interlocking teeth 30 of the panels 12 can include a low friction material or coating 32 that allows the teeth 30 to interconnect without unnecessary friction. The low friction coating 32 can be applied to the interlocking teeth 30 (e.g., a laminate coating) or the teeth 30 can be manufactured from an entirely different material from the rest of the panels 12. With a low friction coating 32, the interlocking teeth 30 of the panels 30 can be interconnected and disconnected with minimal structural disturbance to surrounding panels 12. Additionally, as depicted in FIGS. 5C and 5D, the panels 12 can include grooves or handles 34 to aid in the assembly and disassembly of an enclosure 10. FIG. 5C illustrates a grooved channel 34 on two sides of the panel 12, wherein an installer can grasp the panel 12 with two hands and place the panel 12 in the appropriate space in the enclosure 10. FIG. 5D similarly depicts a pair of recessed handles 34 in the panels 12.

When the panels 12 are structured panels, the panels 12 consist of a rigid, lightweight, insulating material with a suitable compressive strength such that a wall of panels can support the weight of the entire enclosure 10. The panels 10 can be made from such materials as plastic, mineral fiber, foam or other similar materials. With interconnectable panels 12, such as in FIGS. 5A and 5B, the panels can connect at right angles, as well as other angles, so that the entire rack 22 of equipment 20 can be enclosed without or with minimal alteration of the panels 12.

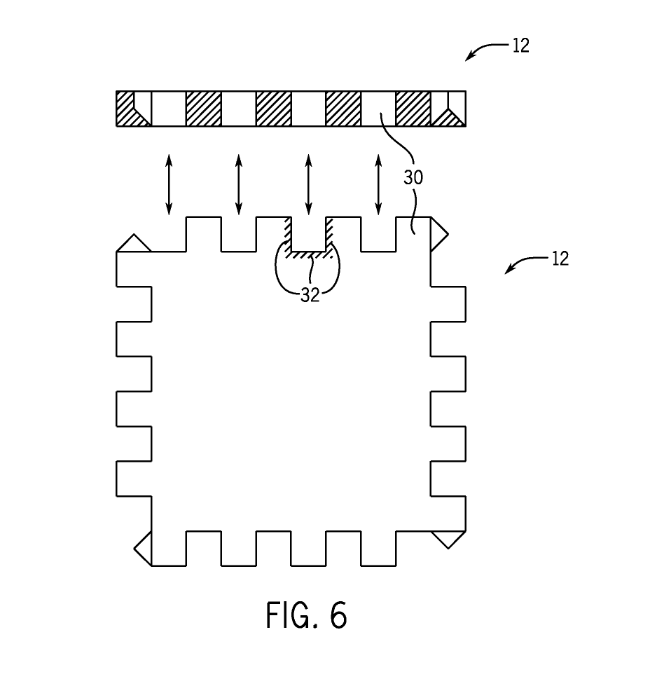

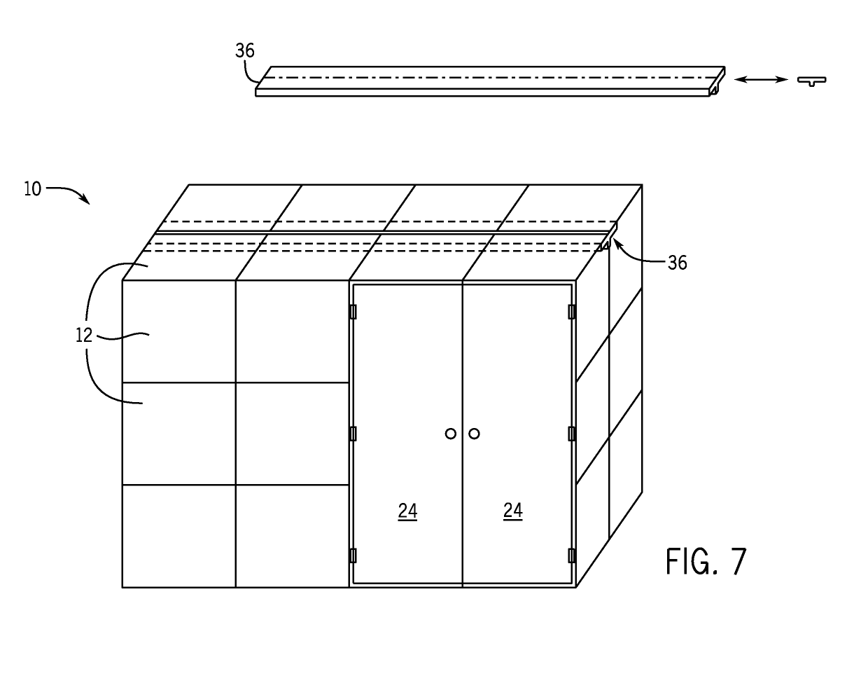

FIG. 6 depicts a front view of a first panel 12 with interlocking teeth 30 and a side view of a second panel 12 with interlocking teeth 30 that interconnect with the first panel 12 at a right angle (e.g., when the wall panels interconnect with the ceiling panels). In FIG. 6, the shaded areas represent recessed areas of the interlocking teeth 30.

When the structured panels 12 are used as ceiling panels a rigid T-shaped member 36 or similar structural member, as depicted in FIG. 7, may be included in the enclosure system 10 to transmit the weight of the ceiling panels 12 onto the wall panels 12. In addition to transmitting the force from the ceiling panels 12 onto the wall panels 12, the T-shaped member 36 prevents the ceiling panels 12 from sagging at the interlocking teeth 30. The T-shaped member 36 can be oriented down, as in FIG. 7, or it can be oriented up. If the T-shaped member 36 is oriented up, the interior interlocking teeth 30 of the panels 12 can simply rest on the T-shaped member 36 instead of interlocking with the panel 12 on the other side of the T-shaped member 36. Additionally, multiple T-shaped members 36 can span the enclosure 10 if necessary to support multiple rows of ceiling panels 12. Various other structural members can accomplish the same function of transmitting the force from the weight of the ceiling panels 12 onto the load bearing wall panels 12; FIG. 7 is merely representative of one embodiment of a structural member that transmits the weight of the ceiling panels 12 onto the walls.

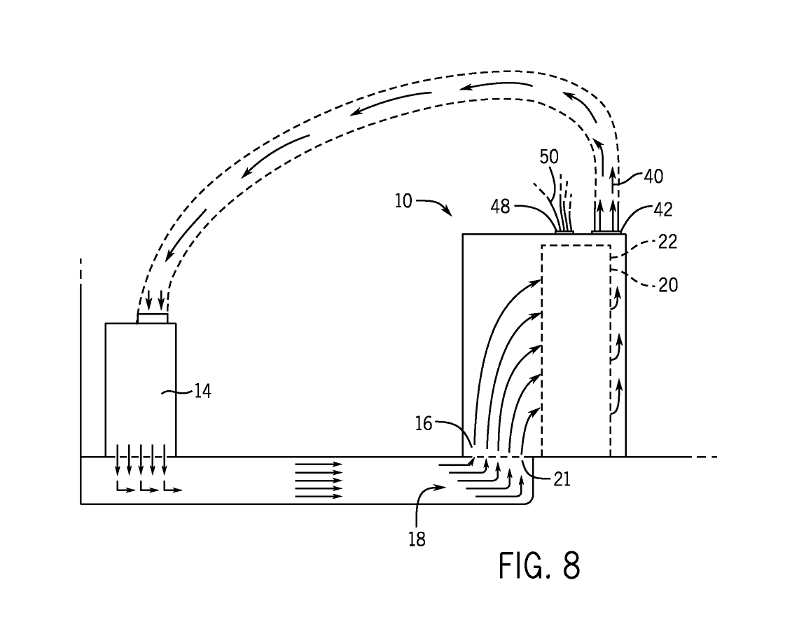

The enclosure system 10 is designed to integrate with the HVAC or CRAC system 14 in the data center or gateway facility. In a typical data center or gateway facility, the CRAC system 14 forces cool air 18 under the flooring and the cool air 18 is deposited through strategically placed perforated floor tiles 16 into the immediate vicinity of the front of a rack 22 of equipment 20 that requires cooling. In the past, and as described previously, the cool air 18 is either contained in a rather large and open “cold” aisle containment space or there is no containment of the cold air 18 (i.e., the cool air is simply forced through the tiles in the general vicinity of the front of the rack 22 of equipment 20). As seen in FIG. 8, the modular enclosure system 100 encapsulates the cool air 18 from the CRAC system 14 by enclosing a portion of the cool air 18 that is forced through the perforated tiles 16. The side walls 12 and front panel(s) 12 extend over all or a portion of the perforated tiles 16 in order to form an efficient cold air containment space in the front area of the rack 22 of equipment 20.

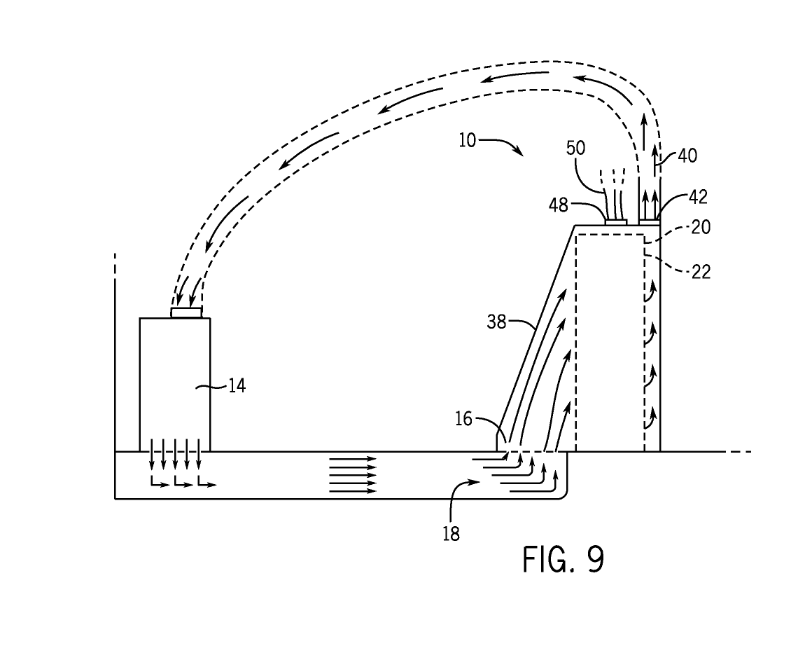

Referring to FIG. 9, the enclosure system 10 can include vents or additional ductwork in the front of the rack 22 of equipment 20 that will further direct the flow of air to the specific equipment on the racks. Also, as depicted in FIG. 9, the shape 38 of the enclosure 10 itself can act as ductwork and force air to flow towards the equipment 20 on the racks 22. For example, the front wall panels 12 that are close to the perforated tiles 16 can angle 38 towards the front of the rack 22 of equipment 20 so that cool air 18 flows towards the equipment 20 in order to improve the flow rate of air into the equipment 20.

The modular enclosure system 10 comprises a system for routing the hot, exhaust air 40 back to the CRAC system 14, while simultaneously controlling the amount of cool air 18 coming into the enclosure 10. The enclosure system 10 may include vented panels 42 for placement in the ceiling of the enclosure 10 that allow hot, exhaust air 40 to flow out of the enclosure 10 and into ductwork that routes the air 40 back to the CRAC system 14. By controlling the flow rate of the exhaust air 40 coming out of each enclosure 10 (i.e., using the appropriate vent size for the outflow of exhaust air), the rate of cool air 18 coming into the enclosure 10 (i.e., rate of cooling) can be controlled. The cooling is controlled because restricting the flow of air out 40 of the enclosure 10 has the effect of restricting the airflow 18 into the enclosure 10. As an example, when the incoming airflow 18 is restricted in a first enclosure 10, the restricted air 18 is forced to subsequent enclosures 10 with an increased rate of flow of cool air 18. In this way, all of the enclosures 10, along with the CRAC system 14, function as a single system. Stated differently, when the outgoing flow of air 40 in the first enclosure is restricted, the restriction has an effect on the flow rate of air in subsequent enclosures 10 and the CRAC system 14. The effect is to reduce the overall load on the CRAC system 14 by supplying an appropriate amount of cooling air 18 to each piece of equipment 20 and reducing the unnecessary cooling of equipment 20.

Alternatively, instead of restricting the airflow out 40 of the enclosure 10 in order to control the flow of air 18 into the enclosure 10, the flow of air can be restricted at the inflow 18 to the enclosure 10 by using perforated floor tiles 16 with differing flow-through areas. Efficiently restricting the outgoing airflow 40 in order to control the incoming flow of air 18 will depend on the effective encapsulation of the enclosure 10. For example, if there are leaks in the enclosure 10, then restricting the outflow 40 may have a reduced impact on restricting the inflow of air 18.

If the rate of outgoing airflow 40 is not restricted by the vented panels 42, then cool air 18 flows into the enclosure 10 at about the same rate as exhaust air 40 flows out of the enclosure 10. In this arrangement, the cool air 18 passes through the equipment 20 at a rate that produces an improved cooling effect, relative to an enclosure with restricted vents 42 in the panels 12. If the outgoing flow of air 40 is restricted, it will create backpressure and the restriction will cause less incoming air 18 to flow into the enclosure and more air 18 to flow into other enclosures 10. In the case of improving the cooling effect, a vented ceiling panel 42 is chosen (or is adjusted, if the vent itself has an adjustable means to control flow rate) that will provide less backpressure (i.e., a vent panel with a relatively larger flow-through area). On the other hand, if an enclosure does not require much cooling, a more restrictive vent panel 42 (i.e., a vent panel with a relatively smaller flow-through area) may be installed. The ability to use different sized vent panels 42 on the ceiling of the enclosure 10 enables an installer to efficiently and easily set and adjust the amount of cooling in each enclosure 10.

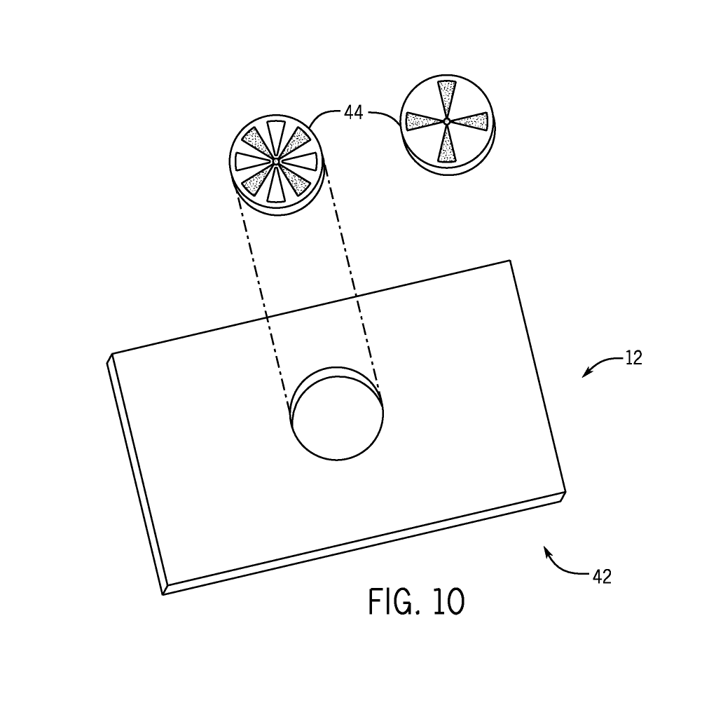

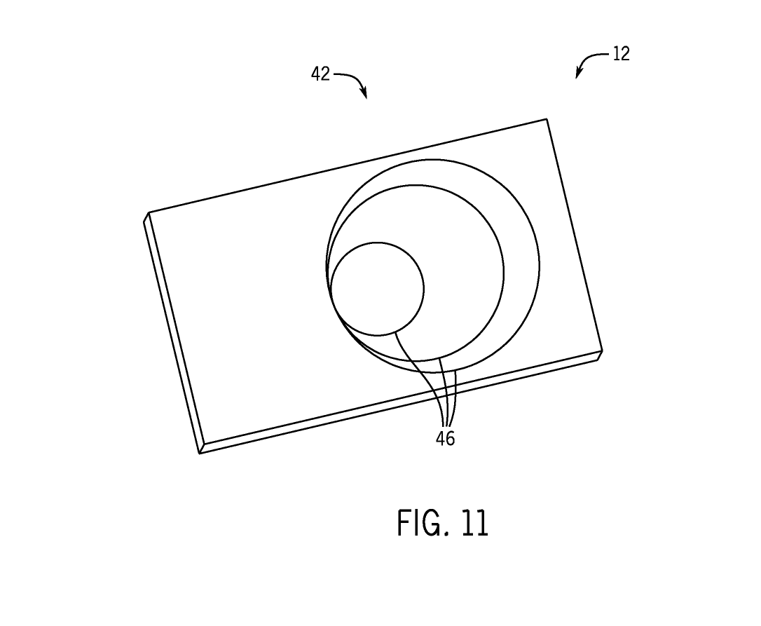

For ease of use and assembly, the vented panels 42 can be the same dimensions and material as the wall and ceiling panels 12. Also, the vented panel 42 may include a standard wall or ceiling panel 12 with a venting element 44 added to the panel 12. Referring to FIG. 10, a vented panel 42 may include a standard wall or ceiling panel 12 that may be modified by cutting a hole into the panel 12, and inserting a venting element 44, for example, a butterfly vent, with an adjustable flow-through area into the hole in the panel 12. Alternatively, referring to FIG. 11, a vented panel 42 may include a standard wall or ceiling panel 12 with cutout indicators 46 marked on the panels 12. An installer can then cut the corresponding sized hole in the panel 12 to achieve the desired flow-through rate. Conversely, the vented panels 42 can be an entirely different material and size from the wall and ceiling panels 12. The above referenced venting options are merely illustrative of the many ways to accomplish an adjustable flow rate of air through the enclosure 10.

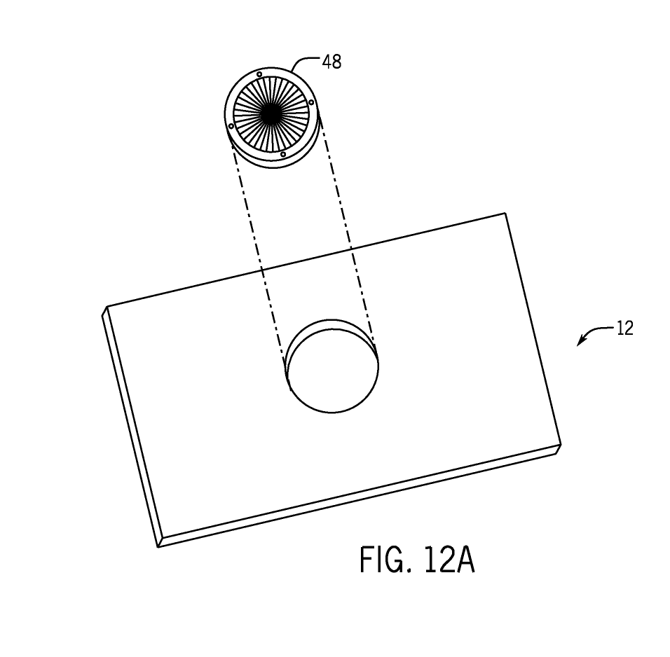

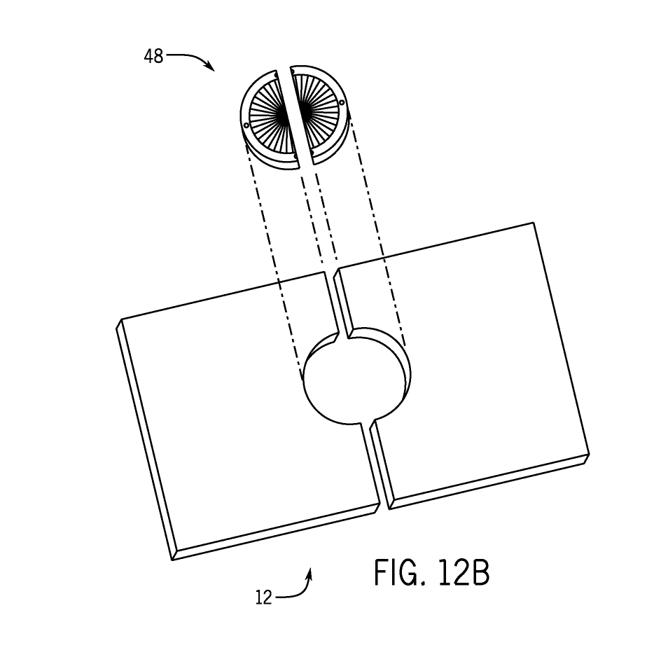

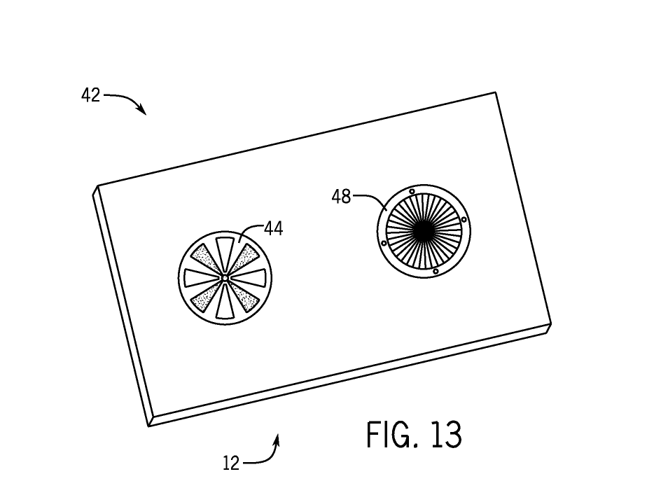

In addition to venting the exhaust air 40, the ceiling panels 12 include cable ports 48 to accommodate the vast network of wires, cords, and cables 50 that must be fed in and out of the enclosure 10 to connect with the equipment 20. Various devices with different sealing membranes may be used to allow cables 50 to pass through the enclosure while allowing minimal bypass of air in and/or out of the enclosure 10. Referring to FIG. 12A, a hole is cut in a standard wall or ceiling panel 12 and a grommet insert with brushes 48 is connected to the panel 12 to allow cables 50 to pass through. In this way, the brushes allow the cables to pass in and out of the enclosure 10 as well as reduce the amount of bypass air that would otherwise escape the enclosure 10 if there were no brushes. Additionally, in FIG. 12B, a spit grommet insert with brushes 48 is used in conjunction with two halves of a standard wall or ceiling panel to allow cables 50 to pass through. In this arrangement, the cables 50 can remain in place (i.e., connected to the equipment 20 in the rack 22), without disconnecting and reconnecting the cables 50, thus there is no downtime with the use of the split grommet insert with brushes 48. Depending on the constraints of the particular modular enclosure 10 or the installer's preference, the cable port 48 can be included in the vented panel 42, as depicted in FIG. 13.

Once the hot air 40 exhausts through the vent panel 42, it then travels through ductwork that either leads to the CRAC system 14 or elsewhere. The ductwork can terminate in a plenum ceiling or otherwise depending on the constraints of the particular data center or gateway facility. If the CRAC system 14 does not cool the exhaust air directly from the enclosure 10, the CRAC system 14 may use cool ambient air from outside the building, outside the data center, or gateway facility. Either way, the ductwork from the enclosure 10 will direct the exhaust air wherever the particular system requires.

As mentioned previously, using vented ceiling panels 42 to restrict the outflow of air 40 will create backpressure in the cooling system. However, restricting the pressure in one enclosure will force the airflow into another enclosure 10. Subsequent enclosures 10 with restrictions of exhaust airflow will further force the airflow into other enclosures 10. The installer that adjusts the flow rate in the enclosures can monitor the overall flow rate of air through the CRAC system 14 to ensure that the unit 14 is not harmed by the backpressure created by the restrictive venting.

In case a particular enclosure requires additional cooling above and beyond that provided by the CRAC system 14, the modular enclosure system 10 may accommodate a dedicated cooling unit (not shown). Because of the customizable nature of the enclosure system 10, a dedicated cooling unit can be attached to the rack 22 and the enclosure 10 can enclose the rack 22 and the cooling unit or the cooling unit can be attached to the outside of the enclosure 10 and the inflow of cool air 18 from the cooling unit can flow through a vented panel 42 and into the enclosure 10.

Although various representative embodiments of this invention have been described above with a certain degree of particularity, those skilled in the art could make numerous alterations to the disclosed embodiments without departing from the spirit or scope of the inventive subject matter set forth in the specification. All directional references (e.g., front, back, rear, side) are only used for identification purposes to aid the reader's understanding of the embodiments of the present invention, and do not create limitations, particularly as to the position, orientation, or use of the invention unless specifically set forth in the claims. Joinder references (e.g., attached, connected, and the like) are to be construed broadly and may include intermediate members between a connection of elements and relative movement between elements. As such, joinder references do not necessarily infer that two elements are directly connected and in fixed relation to each other.

In methodologies directly or indirectly set forth herein, various steps and operations are described in one possible order of operation, but those skilled in the art will recognize that steps and operations may be rearranged, replaced, or eliminated without necessarily departing from the spirit and scope of the present invention. It is intended that all matter contained in the above description or shown in the accompanying drawings shall be interpreted as illustrative only and not limiting. Changes in detail or structure may be made without departing from the spirit of the invention as defined in the appended claims.

1. A modular enclosure system for containing and regulating airflow around electronic and computer related equipment, the system comprising:
a plurality of interconnectable panels, each interconnectable panel defining an outer edge with at least a portion of the outer edge defining a first interconnection pattern, the first interconnection pattern connectable to a second interconnection pattern of an adjacent interconnectable panel to form at least one of a parallel or orthogonal interconnection between the adjacent interconnectable panels,
the plurality of interconnectable panels interconnecting to form a first enclosure around electronic equipment and at least a portion of an airflow from a cool air source, the first enclosure comprising:
a first opening for intaking the at least a portion of the airflow from a cool air source at a first inflow rate into the first enclosure, wherein the at least a portion of the airflow cools the equipment; and
a second opening for exhausting the at least a portion of the airflow out of the first enclosure at a first outflow rate, the second opening comprising a flow-through area that regulates the first outflow rate of the at least a portion of the airflow out of the first enclosure thereby regulating the first inflow rate of the at least a portion of the airflow into the first opening.

2. The modular enclosure system of claim 1, wherein the second opening includes an adjustable opening structure in at least one of the plurality of interconnectable panels such that the flow-through area changes with each variable size.

3. The modular enclosure system of claim 2, wherein the adjustable opening structure comprises a butterfly vent for adjusting the flow-through area.

4. The modular enclosure system of claim 1, wherein the outer edge of each of the plurality of interconnectable panels defines one of a square or a rectangle.

5. The modular enclosure system of claim 4, wherein the first interconnection pattern comprises a first plurality of teeth, and the second interconnection pattern comprises a second plurality of teeth offset from the first plurality of teeth such that the first and the second plurality of teeth interlock.

6. The modular enclosure system of claim 5, wherein the first and the second plurality of teeth define a square-wave pattern.

7. The modular enclosure system of claim 5, wherein the first and the second plurality of teeth further comprise a low friction coating that eases interlocking of the first and the second plurality of teeth.

8. The modular enclosure system of claim 1, wherein the plurality of interconnectable panels are made from a thermally insulating material comprising at least one of plastic, mineral fiber, or foam.

9. The modular enclosure system of claim 1, wherein the first enclosure further comprises a third opening comprising an access door to access the electronic equipment within the first enclosure.

10. The modular enclosure system of claim 1, wherein the first enclosure further comprises a fourth opening for allowing cables to pass into and out of the first enclosure, the fourth opening comprising a sealing membrane that blocks bypass airflow thereby optimizing the first inflow rate and the first outflow rate.

11. The modular enclosure system of claim 10, wherein the sealing membrane is a grommet insert with brushes.

12. The modular enclosure system of claim 1, wherein the cool air source is a computer room air conditioner.

13. The modular enclosure system of claim 1, wherein each of the plurality of interconnectable panels further comprise at least one handle mechanism that eases connection between the first and the second interconnection pattern.

14. The modular enclosure system of claim 1, further comprising a support member that spans a top portion of the first enclosure and supports a positioning of the plurality of interconnectable panels on the top portion of the first enclosure by transferring at least a portion of a weight of the top portion to other portions of the first enclosure.

15. The modular enclosure system of claim 1, wherein the electronic equipment comprises a first rack of electronic equipment and a second rack of electronic equipment, the first enclosure containing the first rack of equipment and the at least a portion of an airflow, the plurality of interconnectable panels interconnecting to form a second enclosure around the second rack of electronic equipment, the second enclosure containing the second rack of equipment and the at least a portion of the airflow, the second enclosure comprising:
a fifth opening for intaking the at least a portion of an airflow from the cool air source at a second inflow rate into the second enclosure; and
a sixth opening for exhausting the at least a portion of the airflow out of the first enclosure at a second outflow rate, the sixth opening comprising a sixth flow-through area that regulates the second outflow rate of the at least a portion of an airflow out of the second enclosure thereby regulating the second inflow rate of the at least a portion of the airflow into the fifth opening.

16. The modular enclosure system of claim 15, wherein regulating the second outflow rate of the at least a portion of the airflow out of the second enclosure regulates the first inflow rate of the at least a portion of the airflow into the first opening of the first enclosure.

17. A modular enclosure kit for containing and regulating airflow around data center or gateway facility equipment, the kit comprising:
a plurality of interconnectable panels, each interconnectable panel defining an outer edge with at least a portion of the outer edge defining a first interconnection pattern, the first interconnection pattern connectable to a second interconnection pattern of an adjacent interconnectable panel to form at least one of a parallel or orthogonal interconnection between the adjacent interconnectable panels,
wherein the plurality of interconnectable panels are adapted to assemble a first enclosure by interconnecting the plurality of interconnectable panels to form an enclosure around electronic equipment to be cooled and at least a portion of an airflow from a cool air source, the enclosure comprising:
a first opening for intaking a portion of a cool airflow to cool the electronic equipment; and
a second opening for exhausting the portion of the cool airflow out of the first enclosure, wherein a size of the second opening is adjustable such that regulating the portion of the cool airflow out of the first enclosure thereby regulates the portion of the cool airflow into the first opening of the enclosure.

18. The modular enclosure kit of claim 17, wherein the outer edge of each of the plurality of interconnectable panels defines one of a square or a rectangle.

19. The modular enclosure system of claim 18, wherein the first interconnection pattern comprises a first plurality of teeth, and the second interconnection pattern comprises a second plurality of teeth offset such that the first and the second plurality of teeth interconnect.

20. The modular enclosure kit of claim 14, further comprising an access door that provides access to an interior of the first enclosure.
